(19) United States
(12) Patent Application Publication
(10) Pub. No.: US 2023/0064309 A1
(43) Pub. Date: Mar. 2, 2023

(54) ELECTROSTATIC CHUCK, SUBSTRATE SUPPORT, PLASMA PROCESSING APPARATUS, AND METHOD OF MANUFACTURING ELECTROSTATIC CHUCK

(71) Applicant: Tokyo Electron Limited, Tokyo (JP)

(72) Inventors: Masanori SATO, Miyagi (JP); Atsushi KAWABATA, Miyagi (JP)

(21) Appl. No.: 17/894,296

(22) Filed: Aug. 24, 2022

(30) Foreign Application Priority Data
Aug. 24, 2021 (JP) 2021-136616

(51) Int. Cl. H01L 21/683; H01J 37/32; B28B 1/00; B33Y 10/00; B33Y 80/00

(52) U.S. Cl. CPC H01L 21/6833; H01J 37/32715; B28B 1/001; B33Y 10/00; B33Y 80/00; H01J 2237/2007; H01J 37/32091

(57) ABSTRACT

An electrostatic chuck for electrostatically attracting a substrate includes: a chuck body formed of first ceramic particles and having a substrate-facing surface facing the substrate attracted to the electrostatic chuck; and a plurality of convex portions formed on the substrate-facing surface of the chuck body, wherein each of the plurality of convex portions excluding at least a tip-side layer is formed of second ceramic particles having a major axis diameter of 20 μm or more and 2,000 μm or less and has a porosity of 0.1% or more and 1.0% or less.

### CROSS-REFERENCE TO RELATED APPLICATION

This application is based upon and claims the benefit of priority from Japanese Patent Application No. 2021-136616, filed on Aug. 24, 2021, the entire contents of which are incorporated herein by reference.

### TECHNICAL FIELD

The present disclosure relates to an electrostatic chuck, a substrate support, a plasma processing apparatus, and a method of manufacturing the electrostatic chuck.

### BACKGROUND

Patent Document 1 discloses an electrostatic chuck device in which an electrostatic attraction surface is formed on one main surface of a base in which an internal electrode for electrostatically attracting a plate-shaped sample is incorporated, a plurality of protrusions is provided on the electrostatic attraction surface, and one or more micro projections are provided on top surfaces of some or all of the plurality of protrusions. In the electrostatic chuck device, the protrusions and the micro projections are made of ceramics.

### PRIOR ART DOCUMENT

### Patent Document

Patent Document 1: Japanese Laid-Open Patent Publication No. 2007-207842

### SUMMARY

According to one embodiment of the present disclosure, there is provided an electrostatic chuck for electrostatically attracting a substrate includes: a chuck body formed of first ceramic particles and having a substrate-facing surface facing the substrate attracted to the electrostatic chuck; and a plurality of convex portions formed on the substrate-facing surface of the chuck body, wherein each of the plurality of convex portions excluding at least a tip-side layer is formed of second ceramic particles having a major axis diameter of 20 μm or more and 2,000 μm or less and has a porosity of 0.1% or more and 1.0% or less.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a configuration example of a plasma processing system.

FIG. 2 is a diagram for explaining a configuration example of a capacitive coupling type of plasma processing apparatus.

FIG. 3 is a sectional view showing an outline of a configuration example of a substrate support.

FIG. 4 is a partially enlarged sectional view of an electrostatic chuck.

FIG. 5 is a flowchart for explaining an electrostatic chuck manufacturing method according to a first embodiment.

FIGS. 6A to 6D are diagrams showing states of a ceramic member in respective steps of the electrostatic chuck manufacturing method according to the first embodiment.

FIG. 7 is a diagram showing an example of the state of the ceramic member in one step of the electrostatic chuck manufacturing method.

FIG. 8 is a partially enlarged sectional view of an electrostatic chuck according to a second embodiment.

FIG. 9 is a flowchart for explaining an electrostatic chuck manufacturing method according to a second embodiment.

FIGS. 10A to 10C are diagrams showing states of a ceramic member in respective steps of the electrostatic chuck manufacturing method according to the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, plasma processing is performed on a substrate such as a semiconductor wafer (hereinafter referred to as “wafer”). In the plasma processing, plasma is generated by exciting a processing gas, and the substrate is processed by the plasma.

The plasma processing is performed in a plasma processing apparatus including a processing chamber and a substrate support. The processing chamber accommodates the substrate support. The substrate support includes an electrostatic chuck that electrostatically attracts the substrate. The electrostatic chuck includes a plurality of convex portions protruding from a surface of a chuck body made of an insulator and supports the substrate by top surfaces of the convex portions. The convex portions are formed of, for example, a sintered body of fine ceramic particles having an average particle diameter of 20 μm or less.

In the plasma processing apparatus, in order to remove contaminants and the like adhering to the electrostatic attraction surface of the electrostatic chuck, dry cleaning of cleaning the interior of the processing chamber with plasma is performed in a state in which the substrate is not placed on the electrostatic chuck. When the convex portions of the electrostatic chuck are formed of the sintered body of fine ceramic particles as described above, the ceramic particles may fall off, that is, particle falling-off may occur when the dry cleaning is performed with plasma. The ceramic particles that have fallen off may cause contamination of the substrate and the like.

Therefore, the technique according to the present disclosure suppresses the generation of contamination-causing substances, i.e., particles from the electrostatic chuck. Hereinafter, an electrostatic chuck, a substrate support, a plasma processing apparatus, and an electrostatic chuck manufacturing method according to the present embodiment will be described with reference to the drawings. In the subject specification and the drawings, elements having substantially the same functional configuration are designated by like reference numerals, and duplicate description thereof will be omitted.

### Plasma Processing System

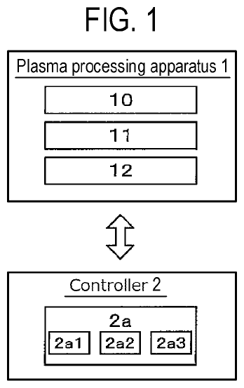

First, the plasma processing system according to an embodiment will be described with reference to FIG. 1. FIG. 1 is a diagram for explaining a configuration example of the plasma processing system.

In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 includes at least one gas supply port for supplying at least one processing gas to the plasma processing space, and at least one gas discharge port for discharging a gas from the plasma processing space. The gas supply port is connected to a gas supplier 20 described later, and the gas discharge port is connected to an exhaust system 40 described later. The substrate support 11 is arranged inside the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), ECR plasma (Electron-Cyclotron-Resonance) plasma, helicon wave plasma (HWP), surface wave plasma (SWP), or the like. Further, various types of plasma generators including an AC (Alternating Current) plasma generator and a DC (Direct Current) plasma generator may be used. In one embodiment, an AC signal (AC power) used in the AC plasma generator has a frequency in a range of 100 kHz to 10 GHz. Therefore, the AC signal includes an RF (Radio Frequency) signal and a microwave signal. In one embodiment, the RF signal has a frequency in a range of 100 kHz to 150 MHz.

The controller 2 processes computer-executable instructions that cause the plasma processing apparatus 1 to perform the various steps described in the present disclosure. The controller 2 may be configured to control each element of the plasma processing apparatus 1 to perform the various steps described herein. In one embodiment, a portion or all of the controller 2 may be included in the plasma processing apparatus 1. The controller 2 may include a processing part 2a1, a memory part 2a2, and a communication interface 2a3. The controller 2 is realized by, for example, a computer 2a. The processing part 2a1 may be configured to perform various control operations by reading a program from the memory part 2a2 and executing the read program. This program may be stored in the memory part 2a2 in advance, or may be acquired via a medium if necessary. The acquired program is stored in the memory part 2a2, and is read from the memory part 2a2 and executed by the processing part 2a1. The medium may be various non-transitory storage media that can be read by the computer 2a, or may be a communication line connected to the communication interface 2a3. The processing part 2a1 may be a CPU (Central Processing Unit). The memory part 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network) or the like.

### Plasma Processing Apparatus

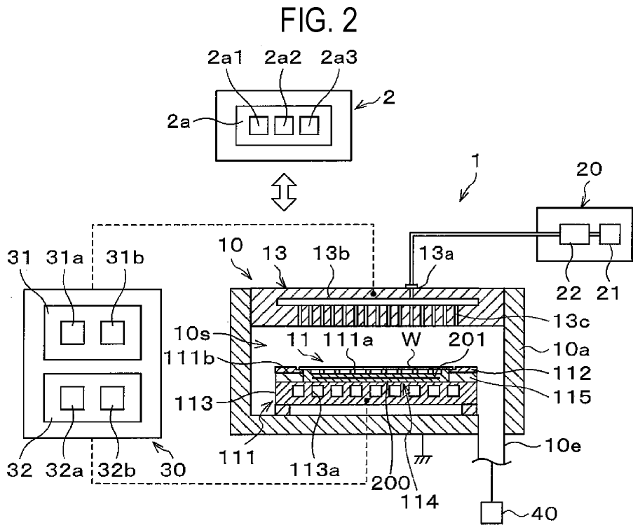

Hereinafter, a configuration example of a capacitive coupling type of plasma processing apparatus as an example of the plasma processing apparatus 1 will be described. FIG. 2 is a diagram for explaining the configuration example of the capacitive coupling type of plasma processing apparatus.

The capacitive coupling type of plasma processing apparatus 1 includes a plasma processing chamber 10, a gas supplier 20, a power supply 30, and an exhaust system 40. Further, the plasma processing apparatus 1 includes a substrate support 11, and a gas introduction part. The gas introduction part is configured to introduce at least one processing gas into the plasma processing chamber 10. The gas introduction part includes a shower head 13. The substrate support 11 is arranged inside the plasma processing chamber 10. The shower head 13 is arranged above the substrate support 11. In one embodiment, the shower head 13 constitutes at least a portion of the ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 includes a central region 111a for supporting the substrate W and an annular region 111b for supporting the ring assembly 112. The wafer is an example of the substrate W. The annular region 111b of the main body 111 surrounds the central region 111a of the main body 111 in a plan view. The substrate W is arranged on the central region 111a of the main body 111, and the ring assembly 112 is arranged on the annular region 111b of the main body 111 so as to surround the substrate W on the central region 111a of the main body 111. Therefore, the central region 111a is also referred to as a substrate support surface for supporting the substrate W, and the annular region 111b is also referred to as a ring support surface for supporting the ring assembly 112.

In one embodiment, the main body 111 includes a base 113 and an electrostatic chuck 114. The base 113 includes a conductive member. The conductive member of the base 113 can function as a lower electrode. The electrostatic chuck 114 is arranged on the base 113. The electrostatic chuck 114 includes a ceramic member 200 and an electrostatic electrode 201 arranged inside the ceramic member 200. The electrostatic chuck 114 has the central region 111a. In one embodiment, the electrostatic chuck 114 also has an annular region 111b. Other members surrounding the electrostatic chuck 114, such as an annular electrostatic chuck and an annular insulating member 115, may have the annular region 111b. In this case, the ring assembly 112 may be placed on the annular electrostatic chuck or the annular insulating member 115, or may be placed on both the electrostatic chuck 114 and the annular electrostatic chuck or the annular insulating member 115. Further, at least one RF/DC electrode coupled to the RF power supply 31 and/or the DC power supply 32 described later may be arranged inside the ceramic member 200. In this case, the at least one RF/DC electrode functions as a lower electrode. When a bias RF signal and/or DC signal, which will be described later, is supplied to the at least one RF/DC electrode, the RF/DC electrode is also referred to as a bias electrode. The conductive member of the base 113 and the at least one RF/DC electrode may function as a plurality of lower electrodes. Further, the electrostatic electrode 201 may function as a lower electrode. Therefore, the substrate support 11 includes at least one lower electrode.

The ring assembly 112 includes one or more annular members. In one embodiment, the one or more annular members include one or more edge rings and at least one cover ring. The edge rings are made of a conductive material or an insulating material, and the cover ring is made of an insulating material.

Further, the substrate support 11 may include a temperature adjustment module configured to adjust at least one of the electrostatic chuck 114, the ring assembly 112 and the substrate W to a target temperature. The temperature adjustment module may include a heater, a heat transfer medium, a flow path 113a, or a combination thereof. A heat transfer fluid such as brine or gas flows through the flow path 113a. In one embodiment, the flow path 113a is formed inside the base 113, and one or more heaters are arranged inside the ceramic member 200 of the electrostatic chuck 114. Further, the substrate support 11 may include a heat transfer gas supplier configured to supply a heat transfer gas to a gap between the back surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. The shower head 13 also includes at least one upper electrode. In addition to the shower head 13, the gas introduction part may include one or more side gas injection portions (SGI: Side Gas Injectors) attached to one or more openings formed in the sidewall 10a.

The gas supplier 20 may include at least one gas source 21 and at least one flow rate controller 22. In one embodiment, the gas supplier 20 is configured to supply at least one processing gas from the corresponding gas source 21 to the shower head 13 via the corresponding flow rate controller 22. Each flow rate controller 22 may include, for example, a mass flow controller or a pressure-controlled flow rate controller. Further, the gas supplier 20 may include at least one flow rate modulation device that modulates or pulses a flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a portion of the plasma generator 12. Further, by supplying the bias RF signal to at least one lower electrode, a bias potential may be generated in the substrate W, and ionic components in the formed plasma may be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma generation. In one embodiment, the source RF signal has a frequency in a range of 10 MHz to 150 MHz. In one embodiment, the first RF generator 31a may be configured to generate multiple source RF signals with different frequencies. One or more source RF signals thus generated is supplied to at least one lower electrode and/or at least one upper electrode.

The second RF generator 31b is coupled to at least one lower electrode via at least one impedance matching circuit and is configured to generate a bias RF signal (bias RF power). A frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals with different frequencies. One or more bias RF signals thus generated are supplied to at least one lower electrode. In various embodiments, at least one of the source RF signal and the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from a DC signal is connected to between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have a positive polarity or a negative polarity. Further, the sequence of voltage pulses may include one or more positive voltage pulses and one or more negative voltage pulses in one cycle. The first and second DC generators 32a and 32b may be provided in addition to the RF power supply 31, or the first DC generator 32a may be provided in place of the second RF generator 31b.

The exhaust system 40 may be connected to, for example, a gas outlet 10e provided at the bottom of the plasma processing chamber 10. The exhaust system 40 may include a pressure regulation valve and a vacuum pump. An internal pressure of the plasma processing space 10s is regulated by the pressure regulation valve. The vacuum pump may include a turbo molecular pump, a dry pump, or a combination thereof.

### First Embodiment

<Substrate Support>

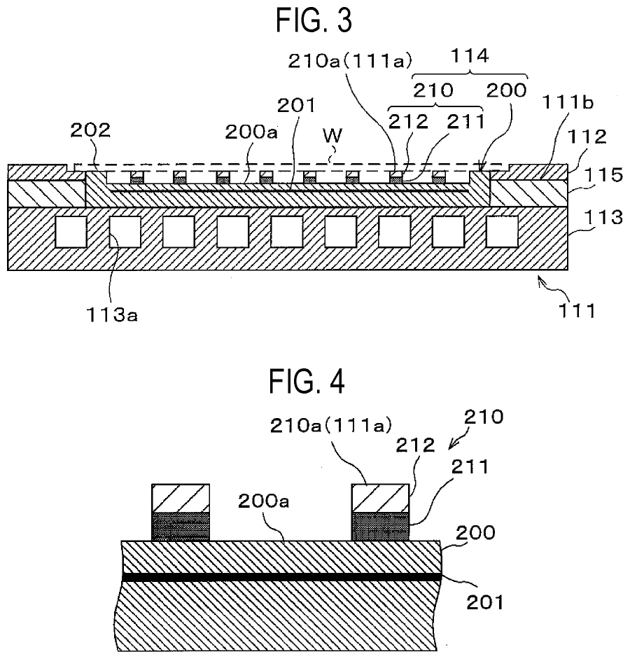

Next, a configuration of the substrate support 11 according to a first embodiment will be described with reference to FIGS. 3 and 4. FIG. 3 is a sectional view showing an outline of a configuration example of the substrate support 11. FIG. 4 is a partially enlarged sectional view of the electrostatic chuck 114.

As described above, the substrate support 11 includes the main body 111 and the ring assembly 112. Further, in one embodiment, the main body 111 includes the base 113, the electrostatic chuck 114, and the annular insulating member 115.

The base 113 is made of a conductive material such as Al or the like. In one embodiment, the base 113 and the electrostatic chuck 114 are integrated by, for example, bonding or the like. Similarly, the base 113 and the annular insulating member 115 are integrated by, for example, bonding or the like.

In one embodiment, the electrostatic chuck 114 is provided on the central portion of the base 113, and the upper surface thereof serves as the above-mentioned central region 111a (hereinafter referred to as a substrate support surface 111a). The electrostatic chuck 114 electrostatically attracts the substrate W. Specifically, the electrostatic chuck 114 electrostatically attracts and supports the substrate W. The electrostatic chuck 114 may electrically attract the substrate W by virtue of a Coulomb force, or may electrically attract the substrate W by virtue of a Johnsen-Rahbek force. As shown in FIGS. 3 and 4, the electrostatic chuck 114 includes a ceramic member 200 as a chuck body and a plurality of (for example, 10 to 100,000) convex portions 210.

The ceramic member 200 is formed of first ceramic particles. The first ceramic particles include, for example, particles of at least one of aluminum oxide, magnesium oxide, yttrium oxide and aluminum nitride. The ceramic member 200 is formed by sintering the first ceramic particles. A porosity (which is a volume ratio (%) of pores to the total volume) of a portion formed of the first ceramic particles in the sintered ceramic member 200 is equal to or less than that of the convex portions 210, for example, 1% or less. Further, a particle size (e.g., major axis diameter) of the first ceramic particles of the sintered ceramic member 200 is smaller than a major axis diameter of the below-mentioned second ceramic particles of the convex portions 210, for example, 1 μm or less. By forming the ceramic member 200 at a porosity of 1% or less, i.e., densely using the small first ceramic particles in this way, it is possible to suppress the falling-off of the first ceramic particles when the interior of the plasma processing chamber 10 is dry-cleaned.

The upper surface 200a of the ceramic member 200 is a substrate-facing surface that faces the substrate W electrostatically attracted to the electrostatic chuck 114. In other words, the ceramic member 200 includes a substrate-facing surface 200a. In one embodiment, a surface roughness of the substrate-facing surface 200a is 0.01 μm or less in terms of arithmetic mean roughness Ra. By processing the substrate-facing surface 200a so as to have such a surface roughness by polishing or the like, the easy-to-fall first ceramic particles existing on the substrate-facing surface 200a can be removed in advance.

Further, inside the ceramic member 200, an electrostatic electrode 201 for electrostatically attracting the substrate W is provided. A DC voltage from a DC power supply (not shown) is applied to the electrostatic electrode 201. Due to the electrostatic force thus generated, the substrate W is attracted and held on the substrate support surface 111a.

In one embodiment, a peripheral portion of the ceramic member 200 is provided with an annular wall portion 202 formed higher than the central portion. Further, for example, the ceramic member 200 is formed to have a diameter smaller than the diameter of the substrate W. When the substrate W is placed on the substrate support surface 111a, the peripheral portion of the substrate W overhangs from the ceramic member 200.

The respective convex portions 210 are formed on the substrate-facing surface 200a of the ceramic member 200 so as to protrude from the substrate-facing surface 200a. The electrostatic chuck 114 supports the substrate W on the endmost surfaces 210a of the convex portions 210. The respective convex portions 210 are formed in a columnar shape (specifically, for example, a cylindrical columnar shape).

Further, a portion (hereinafter referred to as a root-side layer) 211 of each convex portion 210 excluding a tip-side layer 212 is formed of second ceramic particles. Specifically, the root-side layer 211 of each convex portion 210 is formed by sintering second ceramic particles through the use of light. A major axis diameter of the second ceramic particles of the root-side layer 211 after sintering is 20 μm or more and 2,000 μm or less, more preferably 50 μm or more and 1,000 μm or less, even more preferably 100 μm or more and 500 μm or less. The porosity of the root-side layer 211 after sintering is 0.1% or more and 1.0% or less. As the second ceramic particles, ceramic particles having excellent bondability with the below-mentioned single crystal plate constituting the ceramic member 200 and the tip-side layer 212 are used. In one embodiment, the type of the second ceramic particles is the same as that of the first ceramic particles. However, the type of the second ceramic particles may be partially or completely different from that of the first ceramic particles.

Further, a surface roughness of the endmost surface 210a of each convex portion 210 is, for example, 0.01 μm or less in terms of arithmetic mean roughness Ra. In the present embodiment, the tip-side layer 212 including the endmost surface 210a in each convex portion 210 is composed of a single crystal plate, so that the surface roughness of the endmost surface 210a of each convex portion 210 becomes 0.01 μm or less in terms of the arithmetic mean roughness.

As a material of the single crystal plate constituting the tip-side layer 212, a material capable of transmitting light used for sintering the second ceramic particles is used. Further, the material of the single crystal plate constituting the tip-side layer 212 is preferably a material having high strength and wear resistance. Examples of the material of the single crystal plate constituting the tip-side layer 212 may include sapphire (aluminum oxide), magnesia (magnesium oxide), yttria (yttrium oxide), and the like. When a sapphire single crystal plate is used, a plane orientation of the surface that becomes the endmost surface 210a may be a c-plane. This is because the c-plane of the sapphire single crystal plate has a high atomic density.

A thickness of the root-side layer 211 and the tip-side layer 212 (i.e., the single crystal plate) is 10 to 100 μm. An area of the root-side layer 211 and the tip-side layer (i.e., the single crystal plate) in a plan view, i.e., an area of each convex portion 210 in a plan view is, for example, 7×10⁻² mm² to 4.0 mm².

The endmost surface 210a is, for example, a flat surface. However, the endmost surface 210a may be a curved surface that narrows toward the tip. For example, in a case of the plasma processing apparatus 1 that performs a high-power process such as a HARC (High Aspect Ratio Contact) process or the like, the contact area is required to be uniform. Therefore, the endmost surface 210a is formed into a flat surface. Further, for example, in the case of the plasma processing apparatus 1 that performs a low-power process such as a logic process or the like, in which cooling is performed mainly by a cooling gas, it is preferable that the contact area is small from the viewpoint of measures against residual charge. Therefore, the endmost surface 210a is formed into a curved surface. When the endmost surface 210a is a curved surface, for example, a hemispherical single crystal plate is used. A single crystal plate having a curved surface such as a hemispherical shape or the like may be manufactured by, for example, polishing a flat single crystal plate.

The annular insulating member 115 is provided on the peripheral portion of the base 113 so as to surround the electrostatic chuck 114, and the upper surface thereof serves as the ring support surface 111b. A position of the ring support surface 111b is lower than that of the substrate support surface 111a. An electrostatic electrode 201 for electrostatically attracting the ring assembly 112 may be provided inside the annular insulating member 115 to form an annular electrostatic chuck. The annular insulating member 115 (or annular electrostatic chuck) may be integrated with the electrostatic chuck 114.

In one embodiment, the ring assembly 112 may be formed so that when it is supported by the ring support surface 111b, the inner peripheral portion of the ring assembly 112 extends to below the peripheral portion of the substrate W overhanging from the ceramic member 200 as described above.

<Method of Manufacturing the Electrostatic Chuck 114>

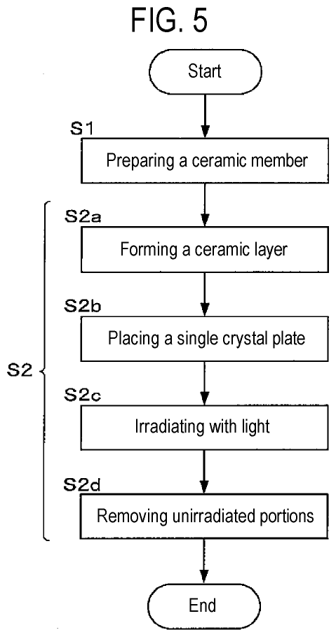

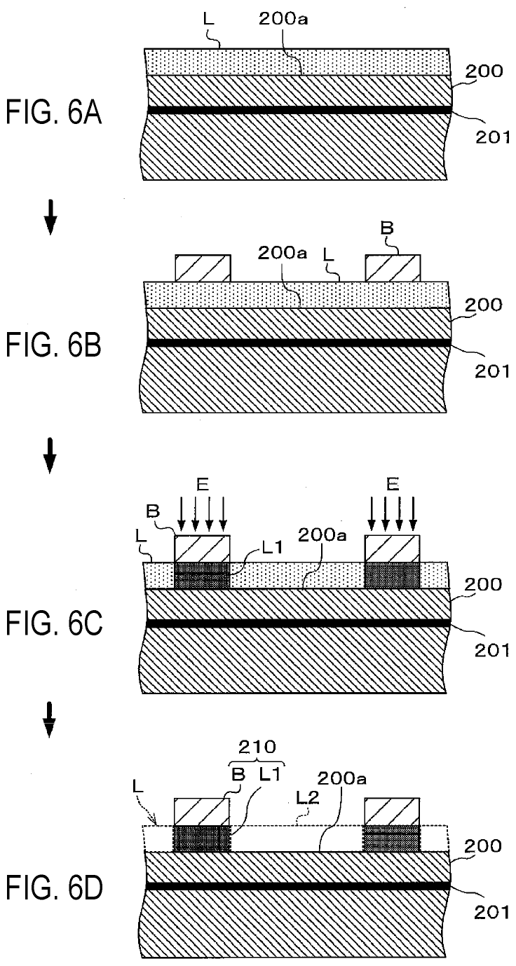

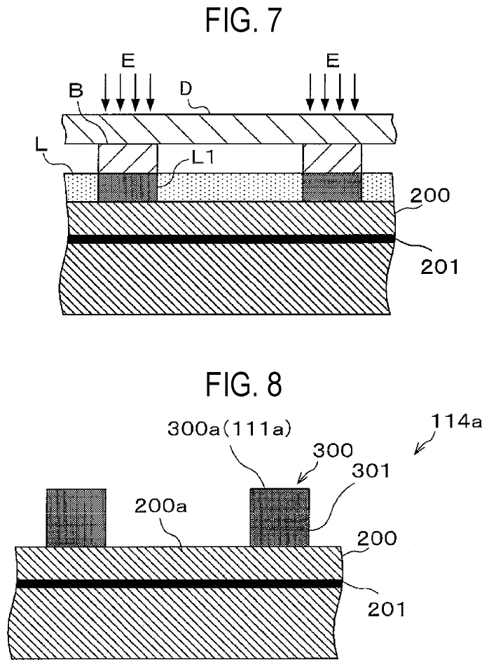

Next, a method of manufacturing the electrostatic chuck 114 according to the first embodiment will be described with reference to FIGS. 5 to 7. FIG. 5 is a flowchart for explaining the method of manufacturing the electrostatic chuck 114 according to the first embodiment. FIGS. 6A to 6D are diagrams showing states of the ceramic member 200 in respective steps of the method of manufacturing the electrostatic chuck 114 according to the first embodiment. FIG. 7 is a diagram showing an example of the state of the ceramic member 200 at the time of step S2c described later.

When manufacturing the electrostatic chuck 114, first, the ceramic member 200 is prepared (step S1). Specifically, for example, first ceramic particles are molded into a plate shape using a mold or the like, and then the molded body of the first ceramic particles is sintered in a pressurized state to produce a plate-shaped sintered body. Two plate-shaped sintered bodies are produced. The two plate-shaped sintered bodies are bonded after the electrostatic electrode 201 is formed between them, thereby producing the ceramic member 200.

When the ceramic member 200 includes the annular wall portion 202, the annular wall portion 202 is formed by grinding, blasting, or the like. Further, in step S1, the substrate-facing surface 200a of the ceramic member 200 may be polished so that the surface roughness thereof is 0.01 μm or less in terms of arithmetic mean roughness Ra. This polishing may be performed before bonding the two plate-shaped sintered bodies, or may be performed after bonding the two plate-shaped sintered bodies. When the ceramic member 200 includes the annular wall portion 202, the substrate-facing surface 200a is polished after the annular wall portion 202 is formed.

Subsequently, the plurality of convex portions 210 is formed on the substrate-facing surface 200a of the ceramic member 200 (step S2).

Specifically, for example, the following steps S2a to S2d are performed. First, as shown in FIG. 6A, a layer L of second ceramic particles is formed on the substrate-facing surface 200a of the ceramic member 200 (step S2a). More specifically, a layer L of second ceramic particles having a particle size distribution such that the porosity after sintering becomes 1% or less is pressure-molded on the substrate-facing surface 200a of the ceramic member 200. The thickness of the pressure-molded layer L of second ceramic particles is 10 μm to 100 μm. In one embodiment, aluminum oxide particles are used for the first ceramic particles and the second ceramic particles, and a sapphire single crystal plate B is used. Further, in another embodiment, aluminum oxide particles are used as the first ceramic particles, an yttria single crystal plate B is used, and a mixture of aluminum oxide particles and yttrium oxide particles is used as the second ceramic particles.

Thereafter, as shown in FIG. 6B, a single crystal plate B (specifically, a chip of a single crystal plate) that transmits light used for sintering the second ceramic particles is placed on the portion corresponding to the convex portions 210 in the layer L of second ceramic particles (step S2b). The single crystal plate B is placed on each of the portions corresponding to the convex portions 210. Each single crystal plate B has a size corresponding to the tip-side layer 212 of each convex portion 210.

Subsequently, the portions of the layer L of second ceramic particles corresponding to the convex portions 210 are selectively irradiated with light, and the irradiated portions L1 are sintered (step S2c). Specifically, as shown in FIG. 6C, the portions of the layer L of second ceramic particles corresponding to the convex portions 210 are irradiated with a laser beam E via the single crystal plate B, and the irradiated portions L1 are sintered. As a result, the major axis diameter of the second ceramic particles of the irradiated portions L1 and the porosity of the irradiated portions L1 are optimized. Specifically, for example, by the light irradiation sintering, the major axis diameter of the second ceramic particles of the irradiated portions L1 is set to 20 μm or more and 2,000 μm or less, and the porosity of the irradiated portions L1 is set to 0.1% or more and 1.0% or less. Further, by the laser light irradiation, the irradiated portions L1 in the layer L of second ceramic particles and the single crystal plate B are bonded to each other, and the irradiated portions L1 and the ceramic member 200 are bonded to each other. In other words, by the laser beam irradiation, the ceramic member 200 and the single crystal plate B are bonded to each other via the irradiated portions L1.

The wavelength of the light used for sintering the second ceramic particles is selected according to the type of the second ceramic particles. When the second ceramic particles are aluminum oxide, for example, light having a wavelength of 500 nm to 1,100 nm may be used. As an example, an Nd: YAG laser (1,064 nm) or a He-Ne laser (543 nm) may be used.

At the time of light irradiation, as shown in FIG. 7, a transparent plate D, which is a plate-shaped member that transmits light, may be pressed against the ceramic member 200 on which the single crystal plate B is placed. Then, in a state in which the transparent plate D is pressed against the ceramic member 200, the portions of the layer L of second ceramic particles corresponding to the convex portions 210 may be irradiated with the sintering light through the transparent plate D and the single crystal plate B. In this case, the transparent plate D is pressed from above so as to collectively contact the plurality of single crystal plates B placed on the layer L of second ceramic particles.

As the transparent plate D, a transparent plate D having a small warp and waviness and having a flat shape (e.g., having a flatness of 0.5 μm or less) is used. Further, the surface roughness of the contact surface of the transparent plate D in contact with the single crystal plate B is equivalent to, for example, the surface roughness of the substrate-facing surface 200a of the ceramic member 200. The transparent plate D is made of a single crystal plate material such as sapphire or the like. However, the transparent plate D may be made of a polycrystalline plate material as long as it can transmit light used for sintering the second ceramic particles. In addition, the transparent plate D may be a Si wafer or a Ge wafer as long as it can transmit light used for sintering the second ceramic particles.

Subsequently, as shown in FIG. 6D, unirradiated portions L2 in the layer L of second ceramic particles, i.e., un-sintered second ceramic particles are removed, and the convex portions 210 having the single crystal plate B are formed (step S2d). The unirradiated portions L2 are removed by cleaning, for example, ultrasonic cleaning or the like.

As described above, the electrostatic chuck 114 according to the present embodiment is manufactured. The bonding between the electrostatic chuck 114 and the base 113 for obtaining the substrate support 11 is performed, for example, after the electrostatic chuck 114 is completed. However, after bonding the ceramic member 200 and the base 113 before the convex portion 210 is formed, the convex portion 210 may be formed on the ceramic member 200 bonded to the base 113. In other words, in step 51, the ceramic member 200 and the base 113 may be bonded to each other.

<Main Effects of the First Embodiment>

As described above, in the electrostatic chuck 114 according to the present embodiment, the root-side layer 211 of each convex portion 210 is formed of the second ceramic particles having a major axis diameter of 20 μm or more and 2,000 μm or less, and the porosity of the root-side layer 211 is 0.1% or more and 1.0% or less. That is, the root-side layer 211 of each convex portion 210 is densely formed of large ceramic particles. If the ceramic particles are large, the particle interface of the ceramic particles is wide, and the porosity is small and dense, the bonding between the ceramic particles is strong. Therefore, it is possible to prevent the ceramic particles constituting the root-side layer 211 from falling off when the interior of the plasma processing chamber 10 is dry-cleaned using plasma. As described above, according to the present embodiment, it is possible to suppress the generation of particles from the electrostatic chuck 114.

Further, in the electrostatic chuck 114 according to the present embodiment, the surface roughness of the endmost surface 210a of each convex portion 210, which is the substrate support surface 111a, is 0.01 μm or less in terms of arithmetic mean roughness Ra. Therefore, when the substrate W is electrostatically attracted to the electrostatic chuck 114, it is possible to prevent a large force from being locally applied from the substrate W to the substrate support surface 111a and prevent the convex portion 210 from being damaged. Further, it is possible to suppress a change in the contact state between the convex portion 210 and the substrate W and a change in the thermal conductivity between the substrate W and the electrostatic chuck 114 due to the damage of the convex portion 210. If the thermal conductivity between the substrate W and the electrostatic chuck 114 is changed, it may become difficult to properly control the temperature of the substrate W by the temperature control module included in the substrate support 11 equipped with the electrostatic chuck 114. However, according to the present embodiment, this can be suppressed.

In a case in which the entire convex portion 210 is formed of small ceramic particles having a particle size (e.g., major axis diameter) of 1 μm or less unlike the present embodiment, the particle interface of the ceramic particles becomes narrow. Therefore, the endmost surface 210a of the convex portion 210 and the substrate W come into contact with each other, whereby the ceramic particles constituting the convex portion 210 are likely to fall off from the endmost surface 210a. Similarly, the dry cleaning of the interior of the plasma processing chamber 10 using plasma tends to cause particle falling-off from the endmost surface 210a of the convex portion 210. On the other hand, in the present embodiment, the tip-side layer 212 of the convex portion 210 including the endmost surface 210a is formed of a single crystal plate. Therefore, since no grain boundary exists between the ceramic particles, it is possible to suppress particle falling-off from the endmost surface 210a, which may otherwise be caused by the contact between the endmost surface 210a and the substrate W, and the dry cleaning inside the plasma processing chamber 10 using plasma.

Further, in the method of manufacturing the electrostatic chuck 114 according to the present embodiment, the ceramic member 200 having the substrate-facing surface 200a is manufactured, and then the convex portions 210 are formed on the substrate-facing surface 200a. As a method different from the method according to the present embodiment, a method of forming convex portions having the same shape as the convex portions 210 by cutting a ceramic plate material and forming a substrate-facing surface (hereinafter referred to as a comparative method) may be considered. With this comparative method, it is difficult to freely process the substrate-facing surface. On the other hand, in the method of manufacturing the electrostatic chuck 114 according to the present embodiment, the substrate-facing surface 200a can be freely processed, and therefore, a process capable of suppressing particle falling-off can be performed. The process capable of suppressing particle falling-off with respect to the substrate-facing surface 200a is a polishing process in which the surface roughness of the substrate-facing surface 200a is set to 0.01 μm or less in terms of arithmetic mean roughness Ra. By such a polishing process, it is possible to remove the easy-to-fall first ceramic particles which have existed on the substrate-facing surface at the time of forming the ceramic member 200, i.e., at the time of sintering the first ceramic particles.

Further, in the method of manufacturing the electrostatic chuck 114 according to the present embodiment, as described above, the transparent plate D may be pressed against the ceramic member 200 at the time of light irradiation for forming the convex portions 210. By pressing the transparent plate D in this way, the height of the top surface of the single crystal plate B after sintering by light (specifically, a distance from the substrate-facing surface 200a of the ceramic member 200 to the top surface of the single crystal plate B) can be suppressed to vary between the single crystal plates B. Therefore, the endmost surface 210a of each convex portion 210 can be brought into contact with the substrate W. In other words, it is possible to prevent the state of contact of the convex portions 210 with the substrate W from varying between the convex portions 210. Further, as described above, the transparent plate D may be a Si wafer. In this case, when the substrate W to be processed is also a Si wafer, the convex portions 210 can be formed while simulating the state of the substrate W at the time of actual processing. Therefore, it is possible to further suppress the variation in the state of contact of the convex portions 210 with the substrate W.

In the electrostatic chuck 114 according to the present embodiment, when the convex portions 210 are worn out or deformed, new convex portions 210 having an appropriate shape may be formed while leaving the worn-out old convex portions 210 as they are. That is, the convex portions 210 can be regenerated. Specifically, the convex portions 210 can be regenerated by performing again the formation of the layer of second ceramic particles on the substrate-facing surface 200a, the placing of the single crystal plate B, the light sintering, and the like, while leaving the old convex portions 210 as they are. The new convex portions 210 are formed, for example, in a region where the old convex portions 210 are not formed. Further, since the old convex portions 210 is lowered due to wear, it is not necessary to remove them. Therefore, at the time of regenerating the convex portions 210, it is possible to regenerate the convex portions 210 more easily than when the old convex portions 210 need to be removed.

Since the electrostatic chuck 114 according to the present embodiment can regenerate the convex portions 210 as described above, it has the following effects. That is, when the convex portions of the electrostatic chuck formed by the above-mentioned comparative method is worn out, a method of re-cutting the portion corresponding to the ceramic member 200 according to the present embodiment is conceivable as the method of regenerating the convex portions. However, in this method, due to the re-cutting or the repetition of re-cutting, the portion corresponding to the ceramic member 200 becomes thin. Therefore, when a voltage is applied to the base 113, the ceramic member 200 may undergo dielectric breakdown. On the other hand, in the case of the electrostatic chuck 114 according to the present embodiment, when regenerating the convex portions 210, the ceramic member 200 does not need to be cut and the ceramic member 200 does not become thin. Therefore, the above-mentioned dielectric breakdown does not occur. Further, in the case of the electrostatic chuck 114 according to the present embodiment, when regenerating the convex portions 210, the electrostatic chuck 114 may or may not be peeled from the base 113. When the peeling is not performed, the convex portions 210 can be regenerated more easily than when the peeling is performed.

In the present embodiment, the foreign substances generated by the wear of the convex portions 210 do not cause contamination of the substrate W because its size is at the atomic size level.

In the above-described embodiment, the single crystal plate is used for the convex portions 210. However, a polycrystalline plate may be used for the convex portions 210 as long as the polycrystalline plate can transmit the light for sintering the second ceramic particles and the major axis diameter of each crystal is 20 μm or more and 2,000 μm or less.

### Second Embodiment

<Electrostatic Chuck>

Next, a configuration of an electrostatic chuck according to a second embodiment will be described with reference to FIG. 8. FIG. 8 is a partially enlarged sectional view of the electrostatic chuck according to the second embodiment.

The configuration of the convex portions is different between an electrostatic chuck 114a according to the present embodiment and the electrostatic chuck 114 according to the first embodiment. In each convex portion 210 of the electrostatic chuck 114 according to the first embodiment, the root-side layer 211 is formed of the second ceramic particles, and the tip-side layer 212 is a single crystal plate. On the other hand, each convex portion 300 of the electrostatic chuck 114a according to the present embodiment, including the root-side layer 301, is entirely formed of the second ceramic particles. Specifically, each convex portion 300 is formed by sintering the second ceramic particles with light. The particle size of the second ceramic particles of the convex portion 300 after sintering is 20 μm or more and 2,000 μm or less, more preferably 50 μm or more and 1,000 μm or less, and even more preferably 100 μm to 500 μm. The porosity of the convex portions 300 after sintering is 0.1% or more and 1.0% or less.

Further, a surface roughness of an endmost surface 300a of each convex portion 300 is, for example, 0.01 μm or less in terms of arithmetic mean roughness Ra, as in the case of the convex portions 210 according to the first embodiment. In the present embodiment, the endmost surface 300a of each convex portion 300 has the above-mentioned surface roughness due to the processing such as polishing or the like.

The height of the convex portions 300 is, for example, 20 to 200 μm. Other shapes and dimensions of the convex portions 300 are the same as those of the convex portions 210 according to the first embodiment.

<Method of Manufacturing the Electrostatic Chuck 114a>

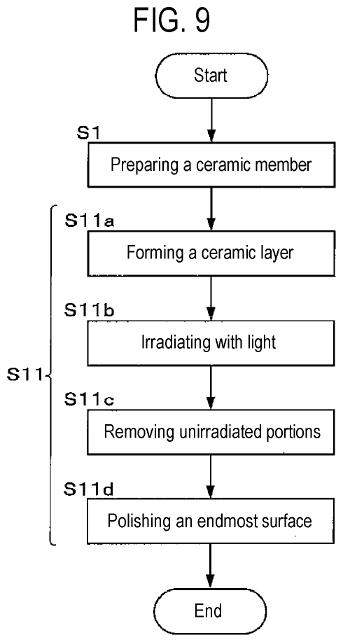

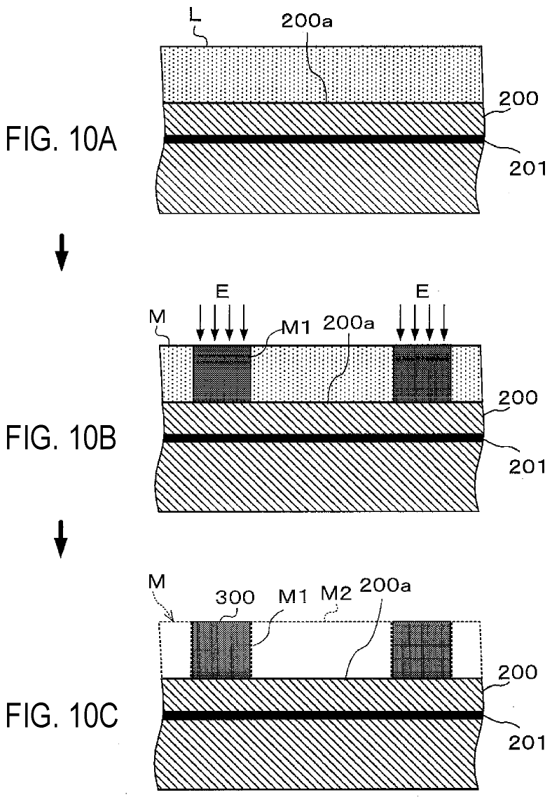

Subsequently, a method of manufacturing the electrostatic chuck 114a according to the second embodiment will be described with reference to FIG. 9 and FIGS. 10A to 10C. FIG. 9 is a flowchart for explaining the method of manufacturing the electrostatic chuck 114a according to the second embodiment. FIGS. 10A to 10C are diagrams showing states of the ceramic member 200 in respective steps of the method of manufacturing the electrostatic chuck 114a according to the second embodiment.

When manufacturing the electrostatic chuck 114a, first, the ceramic member 200 is prepared (step S1).

Subsequently, a plurality of convex portions 300 is formed on the substrate-facing surface 200a of the ceramic member 200 (step S11).

Specifically, for example, the following steps S11a to S11d are performed. First, as shown in FIG. 10A, a layer M of second ceramic particles is formed on the substrate-facing surface 200a of the ceramic member 200 (step S11a). More specifically, a layer M of second ceramic particles having a particle size distribution such that the porosity becomes 1% or less after sintering is pressure-molded on the substrate-facing surface 200a of the ceramic member 200. The thickness of the molded layer M of second ceramic particles is, for example, 20 μm to 200 μm.

Thereafter, as shown in FIG. 10B, portions of the layer L of second ceramic particles corresponding to the convex portions 300 are selectively irradiated with light (specifically, laser light E), and the irradiated portions M1 are sintered (step S11b). As a result, the major axis diameter of the second ceramic particles of the irradiated portions M1 and the porosity of the irradiated portions M1 are optimized. Specifically, by the light irradiation sintering, for example, the major axis diameter of the second ceramic particles of the irradiated portions M1 is set to 20 μm or more and 2,000 μm or less, and the porosity of the irradiated portions M1 is set to 0.1% or more and 1.0% or less. Further, by irradiating the laser beam, the irradiated portions M1 in the layer M of second ceramic particles and the ceramic member 200 are bonded to each other.

Subsequently, as shown in FIG. 10C, unirradiated portions M2 in the layer M of second ceramic particles, i.e., un-sintered second ceramic particles are removed, and the convex portions 300 are formed (step S11c). The unirradiated portions M2 are removed by cleaning, for example, ultrasonic cleaning or the like.

Subsequently, the endmost surface 300a of each convex portion 300 is polished (step S11d). As a result, the surface roughness of the endmost surface 300a of each convex portion 300 is set to 0.01 μm or less in terms of arithmetic mean roughness Ra.

In this way, the electrostatic chuck 114a according to the present embodiment is manufactured.

<Main Effects of the Second Embodiment>

According to the present embodiment, the same effects as those of the first embodiment can be obtained. In the electrostatic chuck 114a according to the present embodiment, at least the root-side layer 301 of each convex portion 300 is formed of the second ceramic particles having a major axis diameter of 20 μm or more and 2,000 μm or less, and the porosity of the root-side layer 301 is 0.1% or more and 1.0% or less. Therefore, it is possible to prevent the ceramic particles constituting the root-side layer 301 of each convex portion 300 from falling off when the interior of the plasma processing chamber 10 is dry-cleaned using plasma.

Further, in the electrostatic chuck 114a according to the present embodiment, the surface roughness of the endmost surface 300a, which is the substrate support surface 111a, is 0.01 μm or less in terms of arithmetic mean roughness Ra. Therefore, when the substrate W is electrostatically attracted to the electrostatic chuck 114a, it is possible to prevent a large force from being locally applied from the substrate W to the substrate support surface 111a and prevent the convex portion 300 from being damaged. Further, it is possible to suppress a change in the contact state between the convex portion 300 and the substrate W and a change in the thermal conductivity between the substrate W and the electrostatic chuck 114a due to the damage of the convex portion 300.

In the present embodiment, the convex portions 210 including the endmost surface 210a are formed of the second ceramic particles having a major axis diameter of 20 μm or more and 2,000 μm or less. Therefore, since the particle interface of the ceramic particles is wide, it is possible to suppress the particle falling-off from the endmost surface 300a due to the contact between the endmost surface 210a and the substrate W and due to the dry cleaning in the plasma processing chamber 10 using plasma.

Further, in the method of manufacturing the electrostatic chuck 114a according to the present embodiment, just like the method according to the first embodiment, the substrate-facing surface 200a can be freely processed, and the process capable of suppressing particle falling-off can be performed.

In the electrostatic chuck 114a according to the present embodiment, just like the electrostatic chuck 114 according to the first embodiment, when the convex portions 300 are worn or deformed, new convex portions 300 having an appropriate shape can be formed while leaving the worn old convex portions 300 as they are. For example, by forming the layer of second ceramic particles on the substrate-facing surface 200a so as to cover the worn-out and shortened old convex portions 300 and then irradiating the existence positions of the old convex portions 300 with light, it is possible to regenerate the old convex portions 300 so as to have the original height (length). Therefore, just like the electrostatic chuck 114 according to the first embodiment, when regenerating the convex portions 300, there is no possibility that dielectric breakdown occurs in the ceramic member 200, and the convex portions 300 can be regenerated with ease.

According to the present disclosure in some embodiments, it is possible to suppress generation of particles from an electrostatic chuck.

The embodiments disclosed herein should be considered to be exemplary and not limitative in all respects. The above-described embodiments may be omitted, replaced, or modified in various forms without departing from the scope of the appended claims and their gist.

What is claimed is:

1. An electrostatic chuck for electrostatically attracting a substrate, comprising:
a chuck body formed of first ceramic particles and having a substrate-facing surface facing the substrate attracted to the electrostatic chuck; and
a plurality of convex portions formed on the substrate-facing surface of the chuck body,
wherein each of the plurality of convex portions excluding at least a tip-side layer is formed of second ceramic particles having a major axis diameter of 20 μm or more and 2,000 μm or less and has a porosity of 0.1% or more and 1.0% or less.

2. The electrostatic chuck of claim 1, wherein a surface roughness of an endmost surface of each of the plurality of convex portions is 0.01 μm or less in terms of an arithmetic mean roughness.

3. The electrostatic chuck of claim 2, wherein the tip-side layer of each of the plurality of convex portions is a single crystal plate.

4. The electrostatic chuck of claim 3, wherein a surface roughness of the substrate-facing surface of the chuck body is 0.01 μm or less in terms of an arithmetic mean roughness.

5. The electrostatic chuck of claim 2, wherein each of the plurality of convex portions, including the tip-side layer, is entirely formed of the second ceramic particles having the major axis diameter of 20 μm or more and 2,000 μm or less, and has the porosity of 0.1% or more and 1.0% or less.

6. The electrostatic chuck of claim 1, wherein a surface roughness of the substrate-facing surface of the chuck body is 0.01 μm or less in terms of an arithmetic mean roughness.

7. A substrate support, comprising:
the electrostatic chuck of claim 1; and
a base having an upper surface on which the electrostatic chuck is provided.

8. A plasma processing apparatus, comprising:
the substrate support of claim 7; and
a processing chamber configured to be depressurized and accommodate the substrate support.

9. An electrostatic chuck for electrostatically attracting a substrate, comprising:
a chuck body formed of first ceramic particles and having a substrate-facing surface facing the substrate attracted to the electrostatic chuck; and
a plurality of convex portions formed on the substrate-facing surface of the chuck body,
wherein the plurality of convex portions are formed by forming a layer of second ceramic particles on the substrate-facing surface of the chuck body, selectively irradiating portions of the layer of the second ceramic particles corresponding to the plurality of convex portions with light so that a major axis diameter of the second ceramic particles in irradiated portions is set to 20 μm or more and 2,000 μm or less and a porosity of the irradiated portions is set to 0.1% or more and 1.0% or less, and subsequently removing unirradiated portions in the layer of the second ceramic particles.

10. A method of manufacturing an electrostatic chuck for electrostatically attracting a substrate, the method comprising:
preparing a chuck body formed of first ceramic particles and having a substrate-facing surface facing the substrate attracted to the electrostatic chuck; and
forming a plurality of convex portions, which protrude from the substrate-facing surface of the chuck body, on the substrate-facing surface of the chuck body,
wherein the forming the plurality of convex portions includes:
forming a layer of second ceramic particles on the substrate-facing surface of the chuck body;
selectively irradiating portions of the layer of the second ceramic particles corresponding to the plurality of convex portions with light so that a major axis diameter of the second ceramic particles in irradiated portions is set to 20 μm or more and 2,000 μm or less and a porosity of the irradiated portions is set to 0.1% or more and 1.0% or less; and
removing unirradiated portions in the layer of the second ceramic particles to form the plurality of convex portions.

11. The method of claim 10, wherein the forming the plurality of convex portions further includes:
placing at least one single crystal plate through which the light transmits, on the portions of the layer of the second ceramic particles corresponding to the plurality of convex portions,
in the selectively irradiating portions of the layer of the second ceramic particles, the layer of the second ceramic particles is irradiated with the light through the at least one single crystal plate, and
in the removing the unirradiated portions, the unirradiated portions are removed, and the plurality of convex portions whose tip-side layer is the at least one single crystal plate are formed.

12. The method of claim 11, wherein the at least one single crystal plate includes a plurality of single crystal plates, and
the selectively irradiating portions of the layer of the second ceramic particles includes:
pressing a transparent plate through which the light transmits against the plurality of the single crystal plates placed on the layer of the second ceramic particles so as to come into contact with the plurality of single crystal plates; and
irradiating the layer of the second ceramic particles with the light through the transparent plate and the plurality of single crystal plates.

13. The method of claim 11, wherein the preparing the chuck body includes polishing the substrate-facing surface of the chuck body so that a surface roughness of the substrate-facing surface is 0.01 μm in terms of an arithmetic mean roughness.

14. The method of claim 10, wherein in the removing the unirradiated portions, the unirradiated portions are removed so that the plurality of convex portions, including a tip-side layer, are entirely formed of the second ceramic particles having the major axis diameter of 20 μm or more and 2,000 μm or less and have the porosity of 0.1% or more and 1.0% or less, and
the forming the plurality of convex portions further includes polishing endmost surfaces of the plurality of convex portions so that a surface roughness of each of the endmost surfaces is 0.01 μm in terms of an arithmetic mean roughness.

15. The method of claim 10, wherein the preparing the chuck body includes polishing the substrate-facing surface of the chuck body so that a surface roughness of the substrate-facing surface is 0.01 μm in terms of an arithmetic mean roughness.
